(19) United States
(12) Patent Application Publication
(10) Pub. No.: US 2016/0072646 A1
(43) Pub. Date: Mar. 10, 2016

(54) APPARATUS COMPRISING A DIFFERENTIAL AMPLIFIER CIRCUIT AND AN EXTRACTION CIRCUIT

(71) Applicant: Fraunhofer-Gesellschaft zur Foerderung der angewandten Forschung e.V., Munich (DE)

(72) Inventors: Jan SUNDERMEYER, Nuernberg (DE); Norbert WEBER, Weissenohe (DE)

(21) Appl. No.: 14/943,504

(22) Filed: Nov. 17, 2015

Related U.S. Application Data
(63) Continuation of application No. PCT/EP2014/059883, filed on May 14, 2014.

(30) Foreign Application Priority Data
May 17, 2013 (DE) 10 2013 209 224.5

(51) Int. Cl. H04L 25/02; H03F 3/45

(52) U.S. Cl. CPC H04L 25/0276; H03F 3/45479; H03F 2203/45082

(57) ABSTRACT

An apparatus with two pairs of lines including a first and second channel further includes a phantom channel that is implemented to provide a third channel without physically installing lines. Based on a differential signal, a first common-mode signal level is generated at a first output of a differential amplifier circuit, and a second common-mode signal level on a second output, and the first common-mode signal level is applied to the lines of the first pair of lines and the second common-mode signal level to the lines of the second pair of lines. An extraction circuit is implemented to extract common-mode portions on the lines of the first pair of lines and the lines of the second pair of lines.

### CROSS-REFERENCE TO RELATED APPLICATIONS

This application is a continuation of copending International Application No. PCT/EP2014/059883, filed May 14, 2014, which is incorporated herein by reference in its entirety, and additionally claims priority from German Application No. 10 2013 209 224.5, filed May 17, 2013, which is also incorporated herein by reference in its entirety.

### BACKGROUND OF THE INVENTION

The present invention relates to an apparatus having a first and second pair of lines for transmitting three signals.

In wired data transmission systems, bidirectional data transmission is either obtained by allocating, as transmission medium, a separate pair of cables each to a forward and a return channel (or transmit and receive channel), or by performing transmitting and receiving on one pair of cables simultaneously in full-duplex operation or in a time-varying manner in half-duplex operation. In all solutions, a maximum of one data stream is transmitted in one direction per pair of cables, wherein this is performed simultaneously in full-duplex operation and in a time-varying manner in half-duplex operation. If a separate pair of cables is used for realizing an additional physical channel, a separate pair of cables can be used continuously for data transmission in each direction.

In the known realizations, the capacity of the cable system is not fully used. For realizing systems necessitating a return channel, there is a choice between reduced system capacity in half-duplex operation, an independent pair of cables or the realization of full-duplex transmission which involves great technical effort. Implementing an independent pair of cables for providing a further data channel, however, involves sometimes enormous financial effort and/or material usage. Additionally, conventional solutions are limited in bandwidth, since the cables are very lossy and possibly comprise local attenuation maxima in a frequency characteristic.

For expanding the transmission rates of several adjacent differential channels, phantom channels can be implemented, by transmitting common-mode signal portions partially separated by means of transducers via the adjacent differential signal paths.

FIG. 2 shows an apparatus 20 according to conventional technology having two bidirectional differential channels 12′a and 12′b. Each channel 12′a and 12′b includes one pair of lines 16a and 16b each, wherein one transducer 44a or 44b each is arranged at two ends of the pair of lines 16a and one transducer 44c and 44d each is arranged at two ends of the pair of lines 16b.

A transducer 44a-d is implemented to transform a signal received on a primary side of the transducer 44a-d from a communication point 13a-d arranged adjacent to the primary side and to apply the same to a pair of lines 16a or 16b arranged on a secondary side, such that the applied signal is applied differentially across the lines of the pair of lines 16a or 16b to the secondary side of a further transducer 44a-d. Further, the transducers 33a-d are implemented to transform a differential signal applied to the secondary side and to provide the same on the primary side for the communication point 13a-d arranged adjacent to the transducer 44a-d, such that the communication point 13a-d receives the provided signal, wherein the communication points 13a-e are implemented to transmit or receive signals.

The transducers 44a-d allow bidirectional transmission of signals via the channels 12′a and 12′b as indicated by the arrows between the lines of the pair of lines 16a and 16b. Signal transmission is performed differentially, such that signals transmitted by means of the transducers 44a-d via the pairs of lines 16a and 16b are common-mode-free (i.e. have no common-mode component).

A phantom channel 26′ includes two transducers 44e and 44f that are centrally coupled, at winding ends of the secondary side of the respective transducer 44e or 44f, to winding centers of the respective secondary side of the transducers 44a-d of the channels 12′a and 12′b, such that a first winding end of the secondary side of the transducer 44a forms a center tap at a winding of the secondary side of the transducer 44a and a second winding end of the secondary side of the transducer 44e forms a center tap on a winding of the secondary side of the transducer 44c. The coupling of the transducers 44b and 44d to the transducer 44s is symmetrical to the coupling of the transducers 44a and 44c to the transducer 44e.

The transducers 44e or 44f are implemented to transform a signal received on the respective primary side from a communication point 13e or 13f, wherein the coupling of the respective secondary side of the transducers 44e and 44f to the transducers of the channels 12′a and 12′b has the effect that a signal from the communication point 13e or 13f is applied to the lines of the pair of lines 16a or 16b as common-mode signal, wherein a first common-mode signal level is applied to the pair of lines 16a and the second common-mode signal level inverted to the first common-mode signal level is applied to the pair of lines 16b.

Due to the coupling of the transducers 44e and 44f to the differential channels 12′a and 12′b, a differential signal is transformed in two common-mode signal levels inverted to one another, and the same are added to the levels of the differential signals applied to the channels 12′a and 12′b. By inverting the common-mode signal levels to one another, again, differential data transmission takes place with regard to the sum of all channels. Considered across the sum of all lines, the signal is also common-mode-free.

The center taps effect a separation of the portions of the differential signals from the common-mode signal levels, such that reconstruction of the differential signal transmitted via the phantom channel takes place in the communication points 13e and f by merging the common-mode signal levels on the secondary sides of the transducers 44e and 44f. The transducers 44a-d filter out the common-mode signal levels based on their wiring, such that a differential signal transmitted via the channel 12′a or 12′b is provided on the primary side of the respective transducer 44a-d, unaffected by the signal transmitted via the phantom channel 26′.

The disadvantage of this implementation according to conventional technology is that the transduction or amplification of the signals is performed by transducers and hence transformers, which are disadvantageous with regard to installation space, costs per unit, energy efficiency and EMC behavior.

### SUMMARY

According to an embodiment, an apparatus may have: a first pair of lines that is implemented to transmit a first differential signal; a second pair of lines that is implemented to transmit a second differential signal; characterized in that the apparatus includes: a differential amplifier circuit comprising two differential amplifiers connected in parallel and that is implemented to generate, based on a third differential signal applied to the inputs of the differential amplifiers connected in parallel, a first common-mode signal level at a first output and a second common-mode signal level at a second output and to apply the first common-mode signal level to the lines of the first pair of lines and to apply the second common-mode signal level to the lines of the second pair of lines, wherein the first common-mode signal level and the second common-mode signal level are inverted to one another; and an extraction circuit for extracting common-mode portions on the lines of the first pair of lines and the lines of the second pair of lines comprising no transducers.

According to another embodiment, a method for transmitting a signal may have the steps of: transmitting a first differential signal via a first pair of lines; transmitting a second differential signal via a second pair of lines; characterized by the steps of: generating a first common-mode signal level at a first output and a second common-mode signal level at a second output with a differential amplifier circuit comprising two differential amplifiers connected in parallel and based on a third differential signal applied to the inputs of the differential amplifiers connected in parallel, such that the first common-mode signal level and the second common-mode signal level are inverted to one another and applying the first common-mode signal level to the lines of the first pair of lines and applying the second common-mode portion to the lines of the second pair of lines; extracting common-mode portions on the lines of the first pair of lines and the lines of the second pair of lines by means of an extraction circuit comprising no transducers.

Embodiments provide an apparatus comprising:
a first pair of lines that is implemented to transmit a first differential signal;
a second pair of lines that is implemented to transmit a second differential signal;
a differential amplifier circuit that is implemented to generate, based on a third signal, a first common-mode signal level at a first output and a second common-mode signal level at a second output and to apply the first common-mode signal level to the lines of the first pair of lines and to apply the second common-mode signal level to the lines of the second pair of lines; and
an extraction circuit for extracting common-mode portions on the lines of the first pair of lines and on the lines of the second pair of lines.

In embodiments of the invention, it is a finding that by applying common-mode signal levels to the lines of different pairs of lines with a differential amplifier circuit and the extraction of common-mode portions, an additional channel can be provided with low loss and without the disadvantages occurring in transducers.

It is an advantage of these inventions that an additionally generated channel can be used as return channel, such that a return channel without capacity loss of the original channels is available for an originally unidirectional communication system and that the return channel has, on the one hand, good characteristics with regard to EMC (electromagnetic compatibility) and on the other hand allows simple technical realization of the channel separation between forward channel and return channel.

According to an embodiment, a phantom channel is provided by expanding two channels, each transmitting a differential signal, such that a third differential signal is applied to the inputs of two differential amplifiers connected in parallel and the outputs of the differential amplifiers are coupled to the lines of original channels such that the third signal in the form of a common-mode signal is applied to lines of the original channels, in addition to the first two differential signals. An extraction circuit filters, with the help of voltage dividers, the common-mode signal portions out of the two differential channels and applies filtered common-mode signal levels to the input of a differential amplifier whose outputs provide the third differential signal for a tap.

It is an advantage of the embodiments that a return channel can be provided by using pairs of lines that are applied to transmit data in one direction, such that bidirectional communication can be established without having to install new physical lines. For realizing the return channel, differential amplifiers are used, which is advantageous with regard to EMC, installation space and cost efficiency.

Further advantages of the present embodiment are: separation between forward and return channel is technically easy to realize, usage of a return channel does not reduce the data capacity of the forward channel, or, in combination with full-duplex data transmission, the overall capacity of a data transmission system can be increased, and in twisted cable systems, for example a star quad wiring or a twisted two-wire line having two, four or eight pairs, good EMC characteristics can be obtained.

### BRIEF DESCRIPTION OF THE DRAWINGS

Embodiments of the present invention will be detailed subsequently referring to the appended drawings, in which:

FIG. 1 is a schematic view of an apparatus having two channels and a phantom channel, wherein the phantom channel includes differential amplifiers;

FIG. 2 is a schematic view of an apparatus according to conventional technology including transducers;

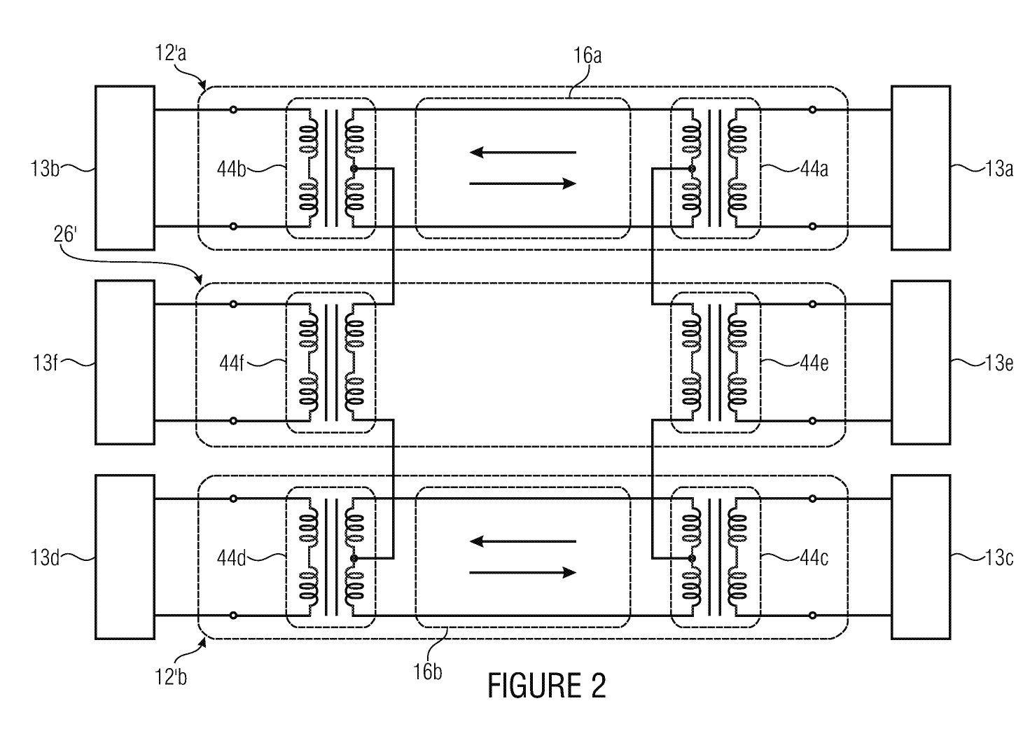

FIG. 3 is a schematic view of a twisted pair of cables.

### DETAILED DESCRIPTION OF THE INVENTION

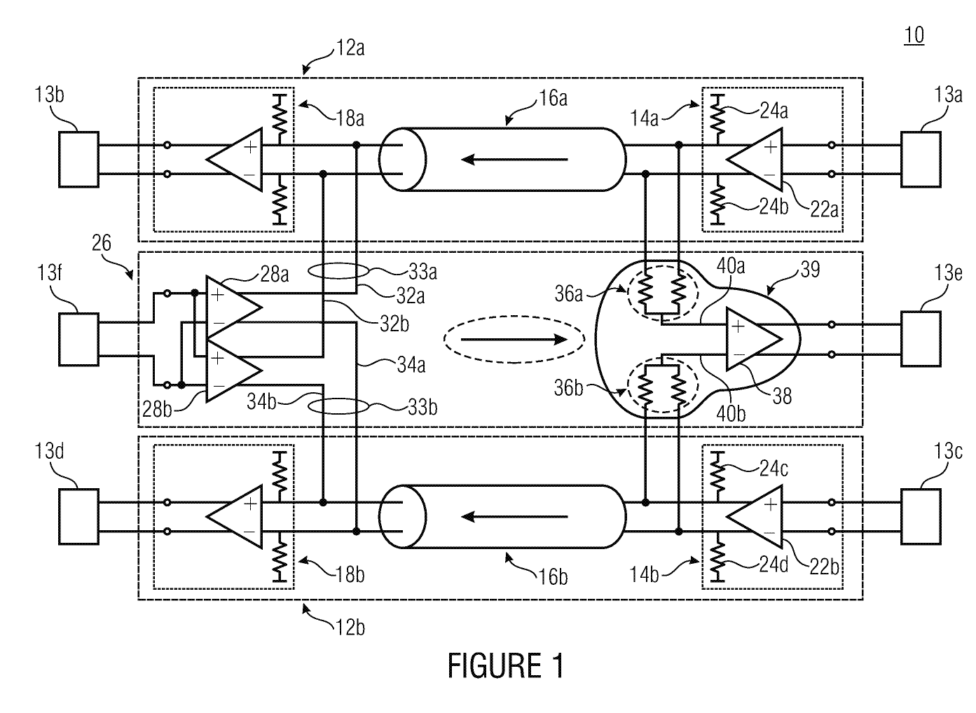

FIG. 1 shows an apparatus 10 having two channels 12a and 12e, each including an output driver 14a or 14b, a differential pair of lines 16a or 16b as well as an input driver 18a or 18b, wherein the first differential pair of lines 16a is implemented to transmit a first signal from a communication point 13a to a communication point 13b, and the second differential pair of lines is implemented to transmit a second differential signal from a communication point 13c to a communication point 13d.

The output drivers 14a or 14b each include a differential current driver 22a or 22b in the form of an operational amplifier driving termination resistors 24a and 24b or 24c and 24c. The output drivers 14a and 14b are implemented to drive an output of the communication point 13a or 13c and to transform, e.g. amplify or smooth, a signal received from the communication point 13a or 13c and to apply the same to the respective pair of lines 16a or 16b.

The differential input drivers 18a or 18b are implemented to receive the signal from the respective differential pair of lines 16a or 16b and to process the same. In the embodiment of FIG. 1, signal transmission is performed from an output driver 14a or 14b towards an input driver 18a or 18b, as indicated by the arrows.

A phantom channel 26 includes two output drivers 28a and 28b that are implemented to receive on the input side a third signal from a communication point 13f and to amplify the same on the output side. The outputs of the output drivers 28a and 28b of the phantom channel 26 are implemented to output one signal of a first polarity 32a or 32b and a second polarity 34a or 34b each and the same are each combined to an output pair having the same polarity. The first polarity 32a or 32b of the outputs of the output drivers 28a or 28b forms a first common-mode signal level 33a, whereas the second polarity 34a or 34b of the outputs of the output drivers 28a or 28b forms a second common-mode signal level 33b. The first common-mode signal level 33a is applied to the differential pair of lines 16a of the channel 12a in that the first polarity 32a is connected to a first line and the first polarity 32b to a second line of the differential pair of lines 16a. The second common-mode signal level is applied to the differential pair of lines 16b of the channel 12b in that the second polarity 34a is connected to a first line and the second polarity 34b to a second line of the differential pair of lines 16b. Due to a symmetrical structure of the circuit of the output driver 28a and 28b of the phantom channel 26, the apparatus is implemented to respectively provide identical signals 32a and 32b or 34a and 34b when applying a signal to the inputs of the output drivers 28a and 28b.

During operation, applying the first polarity 32a and 32b to the lines of the differential pair of lines 16a has the effect that a differential signal applied to the lines of the differential pair of lines 16a is provided with an offset in the form of the first common-mode signal level 33a. Analogously, the second differential signal applied to the differential pair of lines 16b is provided with an offset in the form of the second common-mode signal level 33b.

A channel quality of the differential channels 12a or 12b remains unaffected, since the input drivers 18a and 18b in the form of differential amplifiers effect a separation between the differential signal applied by the output driver 14a or 14b to the lines of the pair of lines 16a or 16b and the common-mode signal levels of the phantom channel by common-mode suppression, by amplifying merely the differences between the two lines of the pair of lines 16a or 16b. The offset by the first or second common-mode signal level 33a or 33b does not affect the difference of the signal level of the respective differential signal and is filtered out at the input drivers 18a and 18b. This suppresses the phantom channel 26 in the differential channels 12, whereby additional echo suppression becomes superfluous.

An extraction circuit 39 comprising two resistive dividers 36a and 36b as well as a differential amplifier 38 and two lines 40a and 40b connecting the outputs of the resistive dividers 36a and 36b to inputs of the differential amplifiers 38 is arranged on a receiver side of the phantom channel 26. The extraction circuit 39 is implemented to extract the signal transmitted via the phantom channel and to suppress the differential signals of the channels 12a and 12b. The differential amplifier 38 is implemented to amplify the difference of the potentials provided at the outputs of the resistive dividers 36a and 36b, wherein the resistive divider 36a is arranged between the lines of the differential pair of lines 16a and the resistive divider 36b is arranged between the lines of the differential pair of lines 16b. An output signal of the resistive divider 36a and an output divider of the resistive divider 36b are applied to a first and a second input of a differential amplifier 38 of the phantom channel 26.

The respective output of the resistive dividers 36a and 36b provides a respective mean value of the signals applied to the differential pair of lines 16a and 16b, such that the differential signal portions are suppressed due to their inversion with respect to one another, and half the amount of the offset formed by the common-mode signal levels 33a or 33b is provided at the respective output of the resistive divider 36a and 36b and that way a common-mode signal in the form of the common-mode signal is filtered out. A potential of the signal on a line 40a between the resistive divider 36a and the differential amplifier 38 corresponds to half the potential of the common-mode signal level 33a, wherein a potential of the signal on the line 40b between the resistive divider 36b and the differential amplifier 38 corresponds to half the potential of the common-mode signal level 33b. The information of the third signal contained in a difference between the first and second common-mode signal levels 33a and 33b is maintained when dividing both potentials in half.

At the outputs, the input driver 38 is coupled to the inputs of the communication point 13e, such that the communication point 13e receives the signal transmitted via the phantom channel 26 and is implemented to drive the input of the communication point 30e. The direction of information transmission of the phantom channel 26 is opposite to the direction of information transmission of the differential channels 12a and 12b, such that the phantom channel 28 forms a return channel with respect to the channels 12a and 12b.

The phantom channel 26 transmits its data via common-mode signal levels 33a and 33b on the lines of the differential pairs of lines 16a and 16b, wherein both common-mode signal levels 33a and 33b are inverted to one another, i.e. again differential data transmission takes place between the two pairs of lines 16a, 16b. Considered across all lines, the signal is still common-mode-free.

The transmission direction of the channels 12a and 12b as well as the phantom channel 26 can be realized arbitrarily, depending on the wiring of output and input drivers 14a, 14b, 18a, 18b, 28a and 28b as well as the extraction circuit 39, such that both signal transmission of channels 12a and 12b in opposite directions is enabled and the phantom channel 26 provides an increase of transmission capacities in one of the two directions, and signal transmission of the phantom channel can be implemented in the same direction as the channels 12a and 12b and the phantom channel 26 achieves the capacity of a unidirectional transmission system.

If, as an alternative to the above description, transmission in full-duplex or half-duplex operation is used, signals can also be transmitted bidirectionally via channels 12a and 12b. In this case, an also bidirectional phantom channel 26 increases the overall capacity of the system. In the case of full-duplex operation, a capacity increase of 50% results.

Contrary to conventional technology, no transducers are used for separating phantom channel 26 and differential channel 12a and 12b. Further, advantages in terms of circuit engineering result by specifically realizing the return channel of a communication system as phantom channel 26, since this makes the maximum data rate available for the main channels 12a and 12b across all pairs of cores.

In particular, when using a star quad cable, but also with twisted pairs of cables having more than one pair of cables, the phantom channel allows data transmission that is performed differentially when considered from outside and that has reduced emission or sensitivity against spurious radiation due to the twisting.

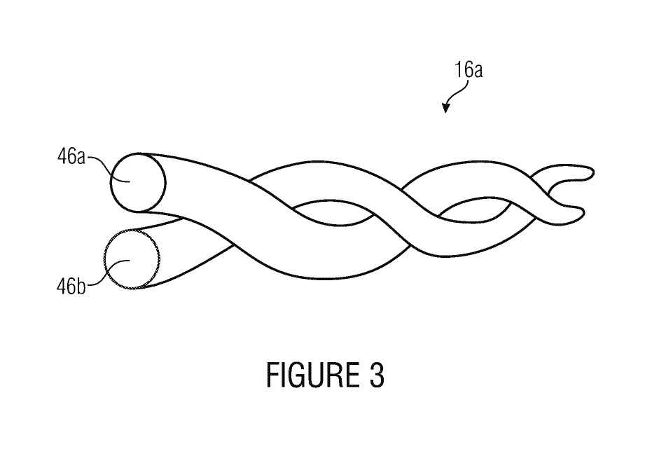

FIG. 3 shows the differential pair of lines 16a including two lines 46a and 46b. In particular for differential signals, twisted lines have advantages with regard to signal attenuation, since the electric or magnetic fields generated by a forward channel are compensated by a return channel twisted with the forward channel due to the electric or magnetic fields of the same.

Alternative embodiments include channels comprising several twisted pairs of cores or where several cores are twisted together.

While this invention has been described in terms of several advantageous embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. Apparatus, comprising:
a first pair of lines that is implemented to transmit a first differential signal;
a second pair of lines that is implemented to transmit a second differential signal; wherein the apparatus comprises:
a differential amplifier circuit comprising two differential amplifiers connected in parallel and that is implemented to generate, based on a third differential signal applied to the inputs of the differential amplifiers connected in parallel, a first common-mode signal level at a first output and a second common-mode signal level at a second output and to apply the first common-mode signal level to the lines of the first pair of lines and to apply the second common-mode signal level to the lines of the second pair of lines, wherein the first common-mode signal level and the second common-mode signal level are inverted to one another; and
an extraction circuit for extracting common-mode portions on the lines of the first pair of lines and the lines of the second pair of lines comprising no transducers.

2. Apparatus according to claim 1 comprising output drivers and input drivers that are implemented to transmit the first signal and the second signal in one direction and to transmit the third signal in an opposite direction.

3. Apparatus according to claim 1, wherein the extraction circuit comprises a differential amplifier.

4. Apparatus according to claim 3, wherein the differential amplifier of the extraction circuit is implemented to amplify the difference of a portion of the first common-mode portion and the second common-mode portion.

5. Apparatus according to claim 1, wherein
the lines of the first pair of lines are twisted in pairs and the lines of the second pair of lines are twisted in pairs.

6. Apparatus according to claim 1, wherein
the lines of the first pair of lines and the second pair of lines comprise a common twisting.

7. Method for transmitting a signal, comprising:
transmitting a first differential signal via a first pair of lines;
transmitting a second differential signal via a second pair of lines; comprising:
generating a first common-mode signal level at a first output and a second common-mode signal level at a second output with a differential amplifier circuit comprising two differential amplifiers connected in parallel and based on a third differential signal applied to the inputs of the differential amplifiers connected in parallel, such that the first common-mode signal level and the second common-mode signal level are inverted to one another and applying the first common-mode signal level to the lines of the first pair of lines and applying the second common-mode portion to the lines of the second pair of lines;
extracting common-mode portions on the lines of the first pair of lines and the lines of the second pair of lines by means of an extraction circuit comprising no transducers.
